(19) United States
(12) Patent Application Publication
(10) Pub. No.: US 2026/0016990 A1
(43) Pub. Date: Jan. 15, 2026

(54) PEAK POWER REDUCTION FOR SYSTEM PARTIAL GOOD BLOCK USAGE

(71) Applicant: Micron Technology, Inc., Boise, ID (US)

(72) Inventors: Yu-Chung Lien, San Jose, CA (US); Jianmin Huang, San Carlos, CA (US); Zhenming Zhou, San Jose, CA (US)

(21) Appl. No.: 19/259,295

(22) Filed: Jul. 3, 2025

Related U.S. Application Data
(60) Provisional application No. 63/671,481, filed on Jul. 15, 2024.

(51) Int. Cl. G06F 3/06

(52) U.S. Cl. CPC G06F 3/0659; G06F 3/0604; G06F 3/064; G06F 3/0679

(57) ABSTRACT

A system includes a memory device with a three-dimensional (3D) memory array having a plurality of blocks. A processing device is coupled to the memory device and determines that a received read command is directed to a partial good block of the plurality of blocks. The processing device identifies, based on the determining, a trim setting associated with a wordline ramping rate of the partial good block. The processing device causes a voltage applied to wordlines of the partial good block to be ramped at a rate according to the trim setting in preparation to perform a read operation in response to the received read command.

### CLAIM OF PRIORITY

The present application claims the benefit under 35 U.S.C. § 119(e) of U.S. Provisional Patent Application No. 63/671,481, filed Jul. 15, 2024, which is incorporated by reference herein.

### TECHNICAL FIELD

Embodiments of the disclosure relate generally to memory sub-systems, and more specifically, enhancements to peak power reduction for system partial good block usage.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments.

FIG. 1B is a block diagram of a memory device in communication with a memory sub-system controller of a memory sub-system, in accordance with some embodiments.

FIG. 2A is a schematic of portions of an array of memory cells as could be used in a memory of the type described with reference to FIG. 1B in accordance with some embodiments.

FIG. 2B is a schematic diagram illustrating a string of memory cells in a data block of a memory device in a memory sub-system in accordance with some embodiments.

FIG. 3A is a diagram illustrating a memory array of a bi-deck memory device in states of full good block and partial good block, in accordance with some embodiments.

FIG. 3B is a diagram illustrating a memory array of a multi-deck memory device in states of third good block and two-thirds good block, in accordance with some embodiments.

FIG. 4 is a simplified circuit diagram of an example charge pump assembly for supplying voltage to wordline drivers in accordance with some embodiments.

FIG. 5A is a flow diagram of an example method of reducing peak power in response to a read command directed at a partial good block in accordance with some embodiments.

FIG. 5B is a flow diagram of a variation on the method of FIG. 5A when the partial good block spans multiple dies of the memory device in accordance with some embodiments.

FIG. 6A is a flow diagram of an example method of reducing peak power in response to a read command directed at a partial good block in accordance with other embodiments.

FIG. 6B is a flow diagram of a variation on the method of FIG. 6A, which deviates when the partial good block is a third or a two-thirds good bock in accordance to some embodiments.

FIG. 7 is a flow diagram of an example method reducing peak power in response to a read command directed at a partial good block in accordance with at least one embodiment.

FIG. 8 is a block diagram of an example computer system in which embodiments of the present disclosure can operate.

### DETAILED DESCRIPTION

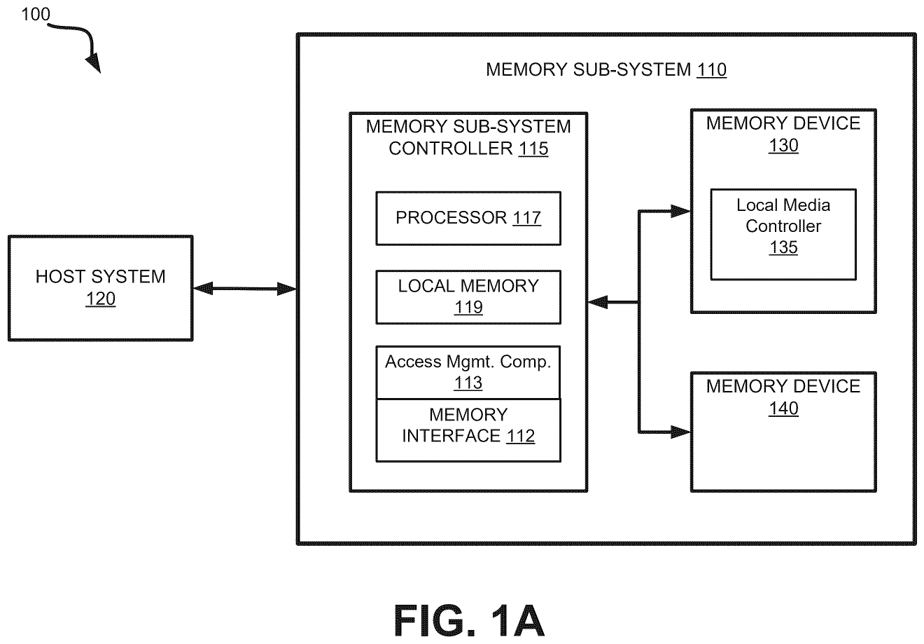

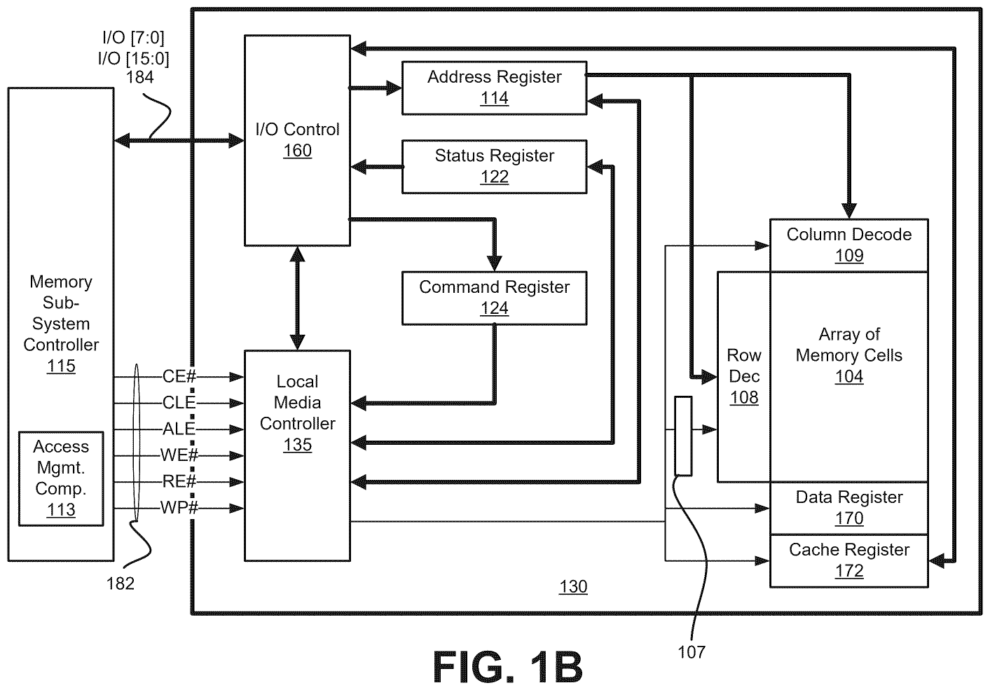

Aspects of the present disclosure are directed at peak power reduction for partial good block usage within a memory sub-system according to some embodiments. A memory sub-system can be a storage device, a memory module, or a combination of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high-density, non-volatile memory devices where retention of data is desired when no power is supplied to the memory device. For example, NAND memory, such as 3D flash NAND memory, offers storage in the form of compact, high-density configurations. A non-volatile memory device is a package of one or more memory dies, each including one or more planes. For some types of non-volatile memory devices (e.g., NAND devices), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1,” or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A data block hereinafter refers to a unit of the memory device used to store data and can include a group of memory cells, a wordline group, a wordline, or individual memory cells. Each data block can include a number of sub-blocks, where each sub-block is defined by a set of associated pillars (e.g., one or more vertical conductive traces) extending from a shared bitline. Memory pages (also referred to herein as “pages”) store one or more bits of binary data corresponding to data received from the host system. To achieve high density, a string of memory cells in a non-volatile memory device can be constructed to include a number of memory cells at least partially surround a pillar of channel material. The memory cells can be coupled to access lines, which are commonly referred to as “wordlines,” often fabricated in common with the memory cells, so as to form an array of strings in a block of memory. The compact nature of certain non-volatile memory devices, such as 3D flash NAND memory, means wordlines are common to many memory cells within a block of memory.

A desire for increased storage capacity in memory devices drives an expansion of block sizes, including an increase of the number of wordlines in each block. The presence of additional wordlines, however, presents certain challenges, including, for example, performance, and reliability penalties attributable to various inefficiencies, e.g., associated with garbage collection or other media management operations for the increased block size. As device sizes increase to accommodate an increase in number of wordlines, manufacturing of the memory devices also becomes more difficult due to the depth increase of etching required to make tall blocks of 3D memory. For example, the sheer sides of etched blocks are closer together at the bottom than at the top of device features, creating inconsistencies in structural dimensions and in device operation across depth of the device.

Certain memory devices are thus divided into multiple segments, sometimes referred to as “decks,” so that width of etching can be more consistent despite the increase in depth. For example, a memory device could include an upper (or “top”) deck and a lower (or “bottom”) deck, each including a respective set of wordlines from the block. Further, a memory device could include the upper deck, the lower deck, and a middle deck positioned between the upper deck and the lower deck, where each deck includes a respective set of wordlines from the block. In this way, memory devices can be divided into arbitrary multi-deck architectures.

Defects in memory devices can impact device performance, reliability, and capacity, and by separating memory devices into multiple decks, new potential points for defects can be introduced. For example, there can arise wordline-to-wordline shorts, an open wordline (e.g., that is not properly connected at some point), or other manufacturing defects that can occur within these individual decks. A deck can be considered “defective” due to one or more defect or structural flaw associated with the memory array of that deck.

For example, due to various factors, such as a manufacturing error, the top deck of a block can be functional while the bottom deck is defective, or the bottom deck of the block can be functional while the top deck is defective (each of which can be referred to as a half good block or HGB). In a multi-deck scenario, such as with three decks, any deck of the three decks can be defective or functional. For example, as will be discussed in detail, a three-deck architecture can lead to a third good block (1/3 GB) where two of three decks are defective and a two-thirds good block (2/3 GB) where only one of the three decks is defective. Some systems can partially recover these “partial good” blocks (i.e., blocks with at least one defective deck) by programming to and reading from the functional decks of these partial good blocks. Because the defective deck(s) are also coupled to a pillar in common with the functional deck(s), memory operations still undertaken at the functional decks can be impacted by threshold voltage states and other parameters associated with the defective deck portion(s). Some of these issues are expected to be compounded in future NAND device manufacturing that increases the number of wordlines in a block.

When programming 3D memory, memory cells coupled to wordlines can be programmed in a memory string from a drain end of the memory string to a source end of the memory string, e.g., from top to bottom of each memory string. At least one reason for this “drain-to-source” (or D₂S) programming order in a regular full block case is because programming in this order reduces the threshold voltage (Vt) shift due to cell-to-cell coupling, e.g., the Vt shift of WLn after WLn+1 is programmed is smaller if WLn+1 is below WLn instead of being above WLn. This reason may only be applicable for programming order within a deck, as being related to the immediate neighbor wordline, for example. Further, there are other advantages to be obtained (e.g., including increasing programming performance and reducing data loss and power consumption) by pre-programming, to some degree, a defective top deck when the goal is to program data to the functional bottom deck.

While advantages can be achieved by some pre-programming of a defective top deck (e.g., prior to programming a functional bottom deck) of a block, there may be no exceptional advantages to altering threshold voltages of a defective deck prior to a read operation. Accordingly, in certain memory devices in handling read operations, the defective deck of a partial good block (regardless of location of the defective deck) can be left in an erased state and no additional action taken to further lower a threshold voltage (Vt) of memory cells coupled to wordlines of the defective deck. In this way, memory cells of the defective deck can stabilize at a low threshold voltage, e.g., effectively retained in an erased state. Doing so also reduces the complexity of handling defective decks during read operations as well as reduces time required to perform the read operations, which are generally expected to be performed quickly.

In some memory devices, however, not further erasing the defective deck in a partial good block can cause a peak current consumption (Icc) (and thus peak power) of memory cells of the partial good block to spike to a dangerous level during a read operation. While the peak Icc tends to occur more often during preparation to complete a read operation of the partial good block, e.g., during a hit voltage pass (Vpass) operation performed before performing read operation(s) on the partial good block, the peak Icc could also occur during the subsequent read operation(s). For example, a current spike of Icc that is too high, e.g., by 5-12 milliamps (mA) or more, can cause a droop in Vcc and possibly cause NAND component malfunction. Further, spikes in the current consumption (or Icc) can cause unwanted excess of peak power. For example, most peak power management (PPM) mode implementations are focused on full good block assumptions and thus may not be directed towards partial good block scenarios. Additionally, the spike in peak Icc can expect to worsen when reading from a partial good block that spans over multiple dies, e.g., due to more available current surge in these situations due to ramping wordlines at multiple dies.

Aspects of the present disclosure address the above and other deficiencies by implementing, during read operations directed at partial good blocks, a trim setting adjustment that impacts the wordline ramping rate of the partial good block. In some embodiments, the impact to the wordline ramping rate is to slow down the ramping rate of wordlines coupled to the partial good block. Thus, in some embodiments, the input clock to a charge pump (also referred to herein as a PCLK), which is coupled to wordline drivers of the partial good block array, can be slowed down by a certain or predetermined amount. For example, a trim setting or clock delay value can be ascertained for a particular type of partial good block and/or depending on the number of dies across which the partial good block spans. This trim setting or clock delay value may then be employed when causing a voltage applied to wordlines of the partial good block to be ramped at a rate, e.g., according to the trim setting (or clock delay value) in preparation to perform a read operation in response to the received read command. In some embodiments, causing the voltage applied to the wordlines to be ramped occurs during a hit pass voltage (Vpass) operation that precedes the read operation, although can also be performed during other pre-read operations or read-affiliated operations.

Advantages of the present disclosure include, but are not limited to, reducing the peak power associated with spikes in current consumption (Icc) of memory cells of a partial good block in preparation for a read operation. By avoiding excess spikes in Icc of the partial good block of memory cells arranged in a string, malfunctions or defects in the memory array due to the excessive peak Icc can also be avoided. Further, slowing down the wordline ramp rate associated with read operations at partial good blocks has no downside for reliability and has fewer read latency penalties compared to a PPM mode, which staggers the operation between each NAND die. Other advantages will be apparent based on the additional details provided herein.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IOT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface component 112. Memory interface component 112 is responsible for handling interactions of memory sub-system controller 115 with the memory devices of memory sub-system 110, such as memory device 130. For example, memory interface component 112 can send memory access commands corresponding to requests received from host system 120 to memory device 130, such as program commands, read commands, or other commands. In addition, memory interface component 112 can receive data from memory device 130, such as data retrieved in response to a read command or a confirmation that a program command was successfully performed. In some embodiments, the memory sub-system controller 115 includes at least a portion of the memory interface 112. For example, the memory sub-system controller 115 can include a processor 117 (processing device) configured to execute instructions stored in local memory 119 for performing the operations described herein. In some embodiments, the memory interface component 112 is part of the host system 110, an application, or an operating system.

In one embodiment, the memory sub-system controller 115 includes a memory device access management component 113 that can, in conjunction with the memory interface 112, oversee, control, and/or manage data access operations, such as program and read operations, performed on a non-volatile memory device, such as memory device 130, of memory sub-system 110. In various embodiments, the memory sub-system controller 115 includes at least a portion of the access management component 113 and is configured to perform the functionality described herein, particularly in relation to identifying partial good blocks and adjusting a trim setting (such as a clock delay value for a charge pump clock) to adjust a wordline ramp rate of a voltage applied to memory cells of partial good block(s). In some embodiments, adjustments to the trim setting (e.g., clock delay value) can be based on the type of partial good block and/or the number of die across which the partial good block spans. In such embodiments, the access management component 113 can be implemented using hardware or as firmware, stored on in the local memory 119 and/or in the memory device 130, executed by the access management component 113 to perform the operations described herein. In some embodiments, one or more operations performed by the access management component 113 are performed by the local media controller 135 or other logic located on-board the memory device 130.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses. In some embodiments, the local media controller 135 is in communication with, and able to control, a charge pump assembly 107 coupled to one or more wordline drivers that drive wordlines of the array of memory cells 104. In some embodiments, the access management component 113 can implement the partial good block usage on a multi-deck memory device, such as memory device 130, by directing the local media controller 135 with one or more commands associated with adjusting the WL ramping rate, including but limited to, adjusting a charge pump clock (or PCLK) of a charge pump within the charge pump assembly 107.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7:0] of I/O bus 184 at I/O control circuitry 160 and may then be written into command register 124. The addresses may be received over input/output (I/O) pins [7:0] of I/O bus 184 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to

FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

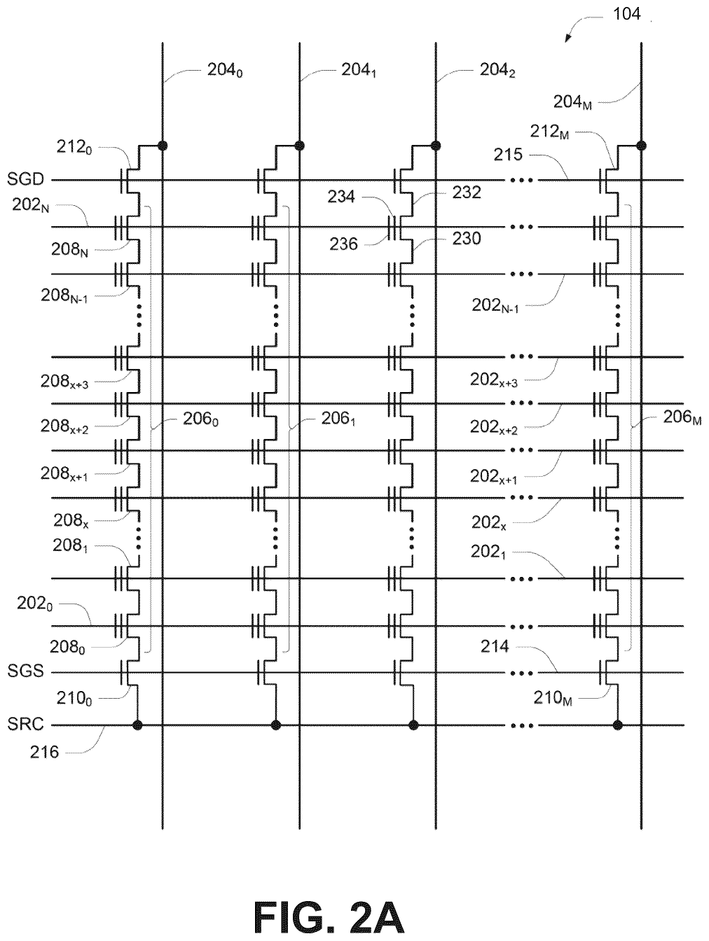

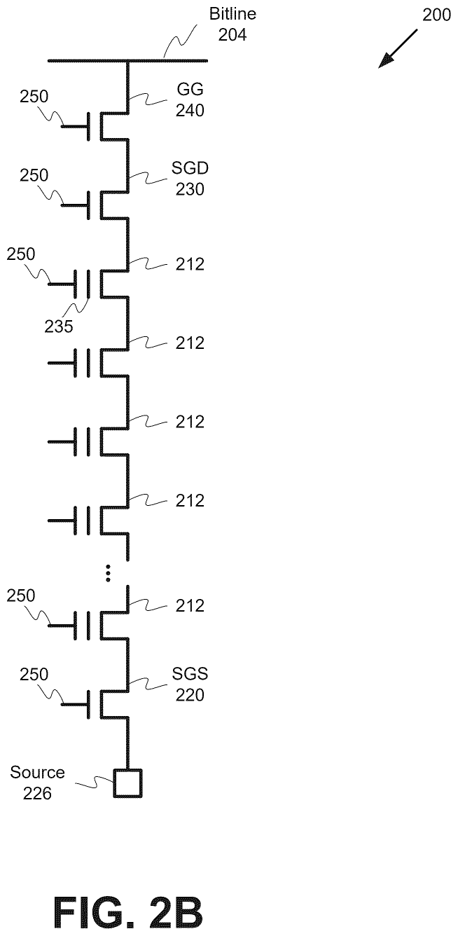

FIG. 2A is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bitlines 204₀ to 204_{M}. The wordlines 202 can be connected to global access lines (e.g., global wordlines), not shown in FIG. 2A, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 104 in FIG. 2A can be a quasi-two-dimensional memory array and can have a generally planar structure, e.g., where the common source 216, NAND strings 206 and bitlines 204 extend in substantially parallel planes. Alternatively, the memory array 104 in FIG. 2A can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2A, it is apparent from the figure that the bitlines 204 of the array of memory cells 104 can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is a schematic diagram illustrating a string 200 of memory cells in a data block of a memory device in a memory sub-system in accordance with some embodiments. In one embodiment, the string 200 is representative of one portion of memory device 130, such as from array of memory cells 104, as shown in FIG. 2A. The string 200 includes a number of memory cells 212 (i.e., charge storage devices), such as up to 32 memory cells (or more) in some embodiments. The string 200 includes a source-side select transistor known as a source select gate 220 (SGS) (typically an n-channel transistor) coupled between a memory cell 212 at one end of the string 200 and a common source 226. The common source 226 may include, for example, a commonly doped semiconductor material and/or other conductive material. At the other end of the string 200, a drain-side select transistor called a drain select gate 230 (SGD) (typically an n-channel transistor) and a gate-induced drain leakage (GIDL) generator 240 (GG) (typically an n-channel transistor) are coupled between one of the memory cells 212 and a data line, which is commonly referred to in the art as a bitline 204. The common source 226 can be coupled to a reference voltage (e.g., ground voltage or simply “ground” [Gnd]) or a voltage source (e.g., a charge pump circuit or power supply which may be selectively configured to a particular voltage suitable for optimizing a programming operation, for example).

Each memory cell 212 may include, for example, a floating gate transistor or a charge trap transistor and may comprise a single level memory cell or a multilevel memory cell. The floating gate may be referred to as a charge storage structure 235. The memory cells 212, the source select gate 220, the drain select gate 230, and the GIDL generator 240 can be controlled by signals on their respective control gates 250.

The control signals can be applied by local media controller 135, or at the direction of access management component 113, to select lines (not shown) to select strings, or to access lines (not shown) to select memory cells 212, for example. In some cases, the control gates can form a portion of the select lines (for select devices) or access lines (for cells). The drain select gate 230 receives a voltage that can cause the drain select gate 230 to select or deselect the string 200. In one embodiment, each respective control gate 250 is connected to a separate wordline (i.e., access line), such that each device or memory cell can be separately controlled. The string 200 can be one of multiple strings of memory cells in a block of memory cells in memory device 130. In one embodiment, wherein memory device 130 is a multi-deck memory device, each of the multiple memory strings can span two or more decks (e.g., a top deck, a bottom deck, and optionally a middle deck), such that certain memory cells 212 in the string 200 are part of the top deck and certain memory cells 212 are part of the bottom deck. For example, when multiple strings of memory cells are present, each memory cell 212 in string 200 may be connected to a corresponding shared wordline, to which a corresponding memory cell in each of the multiple strings is also connected. As such, if a selected memory cell in one of those multiple strings is being programmed, a corresponding unselected memory cell 212 in another string which is connected to the same wordline as the selected cell can be subjected to the same programming voltage, potentially leading to program disturb effects.

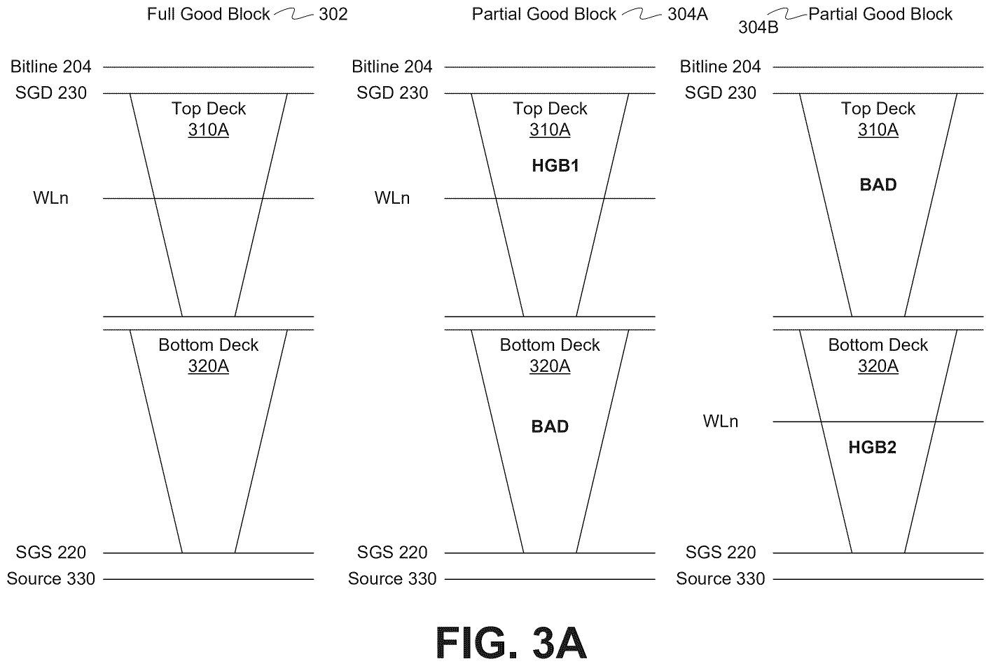

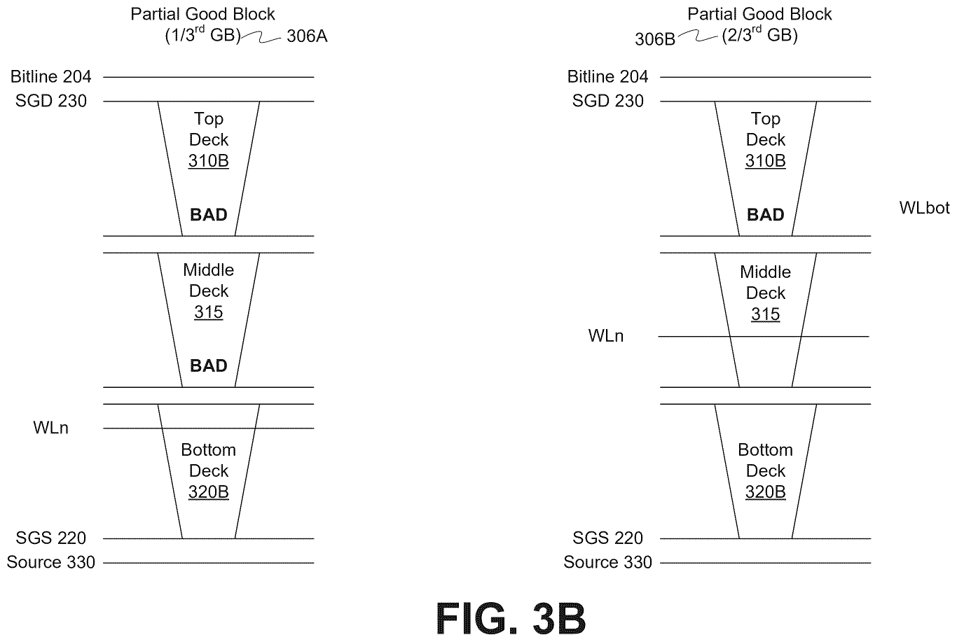

FIG. 3A is a diagram illustrating a memory array of a bi-deck memory device in states of full good block and partial good block, in accordance with some embodiments. Although only two decks (i.e., a top deck 310A and a bottom deck 320A) are illustrated in FIG. 3A, it should be appreciated that certain memory devices can include more than two decks (e.g., three decks, four decks, and the like), an example of which will be discussed with reference to FIG. 3B.

In some embodiments, the top deck 310A and the bottom deck 320A form a full good block 302, where either deck can be programmed and utilized to store system or user data. In other embodiments, however, the top deck 310A and the bottom deck 320A are a part of a partial good block where one of the decks is bad (or defective) and thus cannot be relied upon to store data. In one embodiment, for example, a partial good block 304A is made up of a good top deck 310 (labeled as HGB1) and a defective bottom deck 320A. In another embodiments, the top deck 310 is defective and the bottom deck 320A (labeled as HGB2) is a good deck. As discussed, memory cells selectively coupled to wordlines of good decks can still be reliably programmed with data.

In this way, some pairs of decks can be considered to be a half good block, e.g., partial good block. In at least some embodiments, units of memory cells selectively attached to wordlines of the defective decks of these half good blocks are not erased, e.g., are allowed to be maintained at an already low voltage without further erasure. In embodiments of FIG. 3A, each deck includes a corresponding set of wordlines that are coupled to memory cells arranged in memory strings, such as string 200 (FIG. 2B). In one embodiment, the top deck 310A is arranged vertically above the bottom deck 320A, such that the memory strings can extend from a drain (e.g., bitline 204 accessible via SGD 230) adjacent to the top deck 310B to a source (e.g., source 330 accessible via SGS 220) adjacent to the bottom deck 320A of the memory array.

FIG. 3B is a diagram illustrating a memory array of a multi-deck memory device in states of third good block and two-thirds good block, in accordance with some embodiments. For simplicity of explanation, a three-deck memory device is illustrated by way of example. In some embodiments, the three-deck architecture device includes a top deck 310B, a bottom deck 320B, and a middle deck 315 located in between the top deck 310B and the bottom deck 320B. In some memory devices, extra decks may be necessary due to the increased number of wordlines, e.g., to stabilize the number of wordlines for each deck and avoid over-narrowing of device widths that are being programmed.

In at least some embodiments, partial good blocks under the three-deck memory device example can include a third good block 306A or a two-thirds good block 306B. In a third good block 306A, any of the three decks can be a good deck while the other two decks are defective. The illustrated scenario, by way of example, is that the top deck 310B and the middle deck 315 are defective while the bottom deck 320B is good. Thus, wordlines in the bottom deck 320B can still be programmed. In embodiments, the two-thirds good block 306B can include one deck that is defective while the other two decks are good (e.g., functional). As illustrated by way of example, the top deck 310B is defective while the middle deck 315 and the bottom deck 320B are good. Thus, the wordlines in the middle deck 315 and the bottom deck 320B can still be programmed. While not illustrated, in other embodiments, the bottom deck is defective and either or both of the top deck 310B and the middle deck are good.

In this way, some triplets of decks (e.g., partial good blocks) can be considered to be a third good block or a two-thirds good block. In at least some embodiments, units of memory cells selectively attached to wordlines of the defective decks of these third/two-thirds good blocks are not erased, e.g., are allowed to be maintained at an already low voltage without further erasure. In some embodiments, each deck of the three-deck architecture includes a corresponding set of wordlines that are coupled to memory cells arranged in memory strings, such as string 200 (FIG. 2B). In one embodiment, the top deck 310B is arranged vertically above the middle deck 315, which is arranged vertically above the bottom deck 320B, such that the memory strings can extend from a drain (e.g., bitline 204 accessible via SGD 230) adjacent to the top deck 310B, through the middle deck 315, to a source (e.g., source 330 accessible via SGS 220) adjacent to the bottom deck 320B of the memory array.

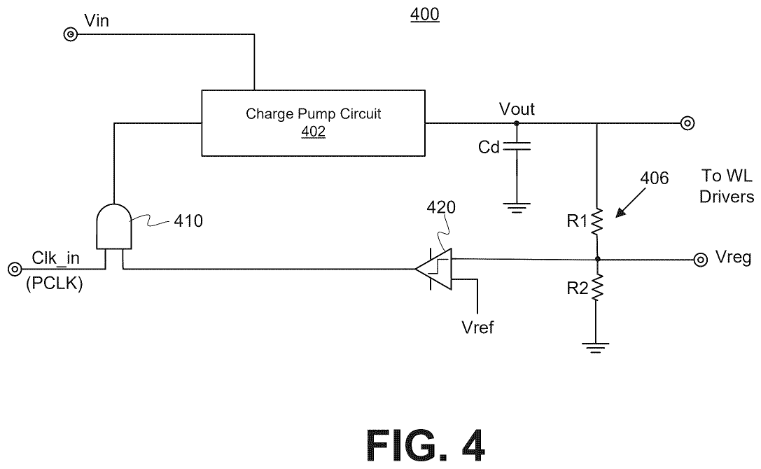

FIG. 4 is a simplified circuit diagram of an example charge pump assembly 400 for supplying voltage to wordline drivers in accordance with some embodiments. In some embodiments, the charge pump assembly 400 is the charge pump assembly 107 of FIG. 1B. For example, the charge pump assembly 400 can increase an input voltage (Vin) to a higher voltage bias, such as for purposes of some memory operations such as to supply a pass voltage (VPASS), a program voltage (VPGM), or a ramping voltage maximum (VERA) when programming. Thus, the charge pump assembly can be coupled to various resistance loads for different memory operations associated with an array of memory cells.

In some embodiments, the charge pump assembly 400 includes a charge pump circuit 402 that generates an output voltage (Vout), which can be employed for higher voltage purposes just discussed. For example, the output voltage can be regulated (e.g., Vreg) to become a VPASS, VPGM, or VERA voltage level by a voltage divider 406 that includes resistors R1 and R2. In differing embodiments, the output voltage may or may not be regulated that is provided to the WL drivers in order to adjust the ramping rate of voltage on wordlines before a read operation. This read operation can be a normal read operation, or another read method or read error handling method such as a correct read, or the like.

In some embodiments, the regulated voltage (Vreg) is fed back into a comparator 420 that compares the regulated voltage with a reference voltage (Vref) so that the charge pump circuit 402 can be directed to keep pumping voltage until reaching the reference voltage. The reference voltage (Vref) can be programmable or modifiable on the fly for different purposes (e.g., different desired regulated voltage levels). An output of the comparator 420 may be supplied to an AND gate 410, which combines, into the comparator output, an input clock (Clk_in), which is also referred to as the charge pump clock (PCLK) herein. This PCLK may be an internal clock and the faster the PCLK speed, the higher the current consumption, but the better the timing performance in memory operations, so there is expected to be a balancing tradeoff between frequency (e.g., PCLK speed) and power consumption.

For example, in at least some embodiments, the access management component 113 adjusts a frequency (or period) of the charge pump clock as a trim setting or parameter (e.g., clock delay value) by sending commands to the local media controller 135, as was discussed with reference to FIG. 1B. In this way, the controller 115 is able to direct the memory device 130 to modify (e.g., slow down) the charge pump clock under certain partial good block conditions, and thus adjust a ramping rate of the wordlines in particular operations. In some embodiments, the operation is a hit pass voltage operation that precedes one or more read operations. By slowing down the wordline ramping rate in partial good block situations, a peak consumption current (or Icc) can be reduced below a peak value to protect the memory array and reduce power consumption, among other advantages discussed herein.

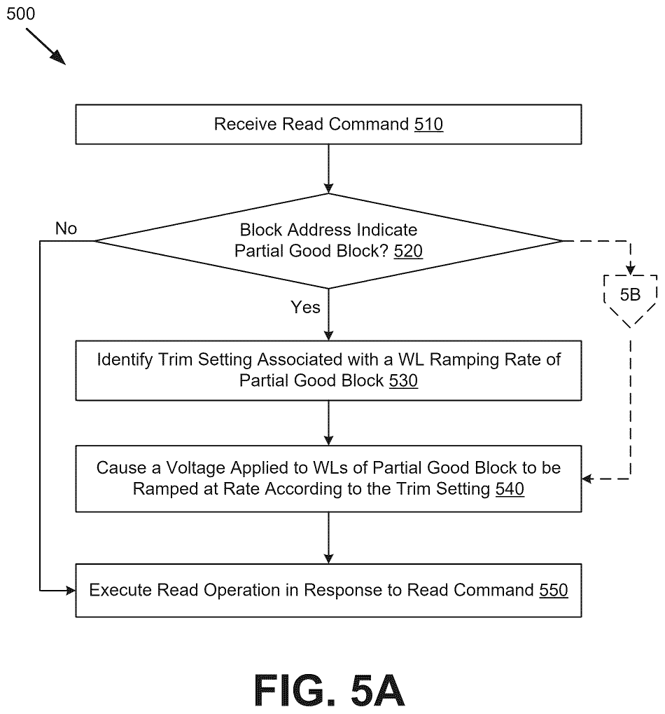

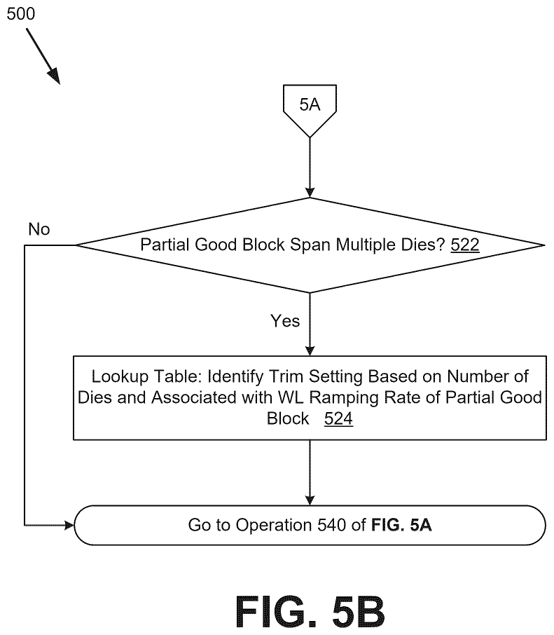

FIG. 5A is a flow diagram of an example method 500 of reducing peak power in response to a read command directed at a partial good block in accordance with some embodiments. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by access management component 113 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, a read command is received. For example, the processing logic (e.g., the access management component 113) receives a read command from host system 120 or another agent seeking access to an array on the memory device 130.

At operation 520, a block address is inspected. For example, the processing logic determines whether the block address of the read command indicates the block being read is a partial good block. If the block being read is not a partial good block, the method 500 can flow to the end to simply execute the read operation without adjusting trim settings. Otherwise, the method 500 flows to operation 530, or optionally to the operations of FIG. 5B.

In some embodiments, determining that the received read command is directed to the partial good block includes accessing a system file (e.g., stored in the local memory 119 or at the array of memory cells 104) in which metadata associated with the plurality of blocks is stored. In embodiments, the metadata in the system file includes an indication of which of the plurality of blocks are partial good blocks. In this way, the metadata associated with particular block addresses can be accessed to determine whether the block is a partial good block.

At operation 530, a trim setting is identified. For example, the processing logic identifies a trim setting associated with a wordline ramping rate of the partial good block. In some embodiments, the trim setting is a clock delay value. In some embodiments, identifying the trim setting (e.g., clock delay value) is performed by accessing a data structure (such as a lookup table) in which the clock delay value is indexed to a type of partial good block. Each type of partial good block could thus be associated with a different clock delay value.

At operation 540, a wordline ramping rate is adjusted. For example, the processing logic causes a voltage to be applied to wordlines of the partial good block to be ramped at a rate according to the trim setting identified at operation 530. In some embodiments, causing the voltage applied to the wordlines to be ramped according to the trim setting includes causing a charge pump clock to be slowed by the clock delay value, the charge pump clock to drive a charge pump that generates the voltage.

At operation 550, the read operation is executed. For example, the processing logic causes the read operation to be performed in response to the read command received at operation 510. At some point before actual read operation execution, e.g., in preparation to perform the read command, or during read operation execution, the processing logic performs operation 540 in order to reduce the peak consumption current level (e.g., Icc peak current), as discussed.

FIG. 5B is a flow diagram of a variation on the method 500 of FIG. 5A when the partial good block spans multiple dies of the memory device in accordance with some embodiments. For example, in response to determining that the block is a partial good block at operation 520, the processing logic can direct additional operations to consider whether the partial good block is a multi-die partial good block. More specifically, at operation 522, the processing logic determines whether the partial good block spans across multiple dies of the memory device. In embodiments, identifying the trim setting is also based on a number of dies of the multiple dies. This determination can be made at least because the larger number of dies that make up the block, the higher the potential peak Icc value, which can demand a slower wordline ramping rate to prevent the potential for too high of a peak power value.

At operation 524, a wordline voltage ramp rate is further adjusted. More specifically, the processing logic identifies the trim setting (e.g., from the aforementioned lookup table) based on the number of dies across which the partial good block spans and which is associated with a wordline ramping rate of the partial good block. In this way, operations 522 and 524 can be seen as a replacement for operation 530 in this variation to the method 500 of FIG. 5A. Upon passing to operation 540 of FIG. 5A, this trim setting (identified at operation 524) can instead be employed in causing the voltage applied to the wordlines of the partial good block to be ramped at an updated (e.g., slowed) rate.

Table 1 illustrates an example data structure or lookup table mentioned with reference to operation 524 in which different PCLK delay values are listed for different partial good block (PGB) situations depending on the number of dies associated with the partial good block. Table 1 contrasts normal full block (FB) default values with example clock delay values, which can be generated in predetermined time periods by employing one or more digital-to-analog converters (DAC) between the PCLK and the charge pump assembly 400. In this way, the processing logic can quickly determine the clock delay value to add to the charge pump clock for purposes of executing a particular read operation (or in preparation to execute a particular read operation).

TABLE 1

| # of Dies | Block Usage | PCLK Setting/Delay |
|---|---|---|
| 1 | FB | Default PCLK |
| | PGB | PCLK + 8 DAC |
| 2 | FB | Default PCLK |
| | PGB | PCLK + 10 DAC |
| 4 | FB | Default PCLK |
| | PGB | PCLK + 12 DAC |
| 8 | FB | Default PCLK |
| | PGB | PCLK + 14 DAC |

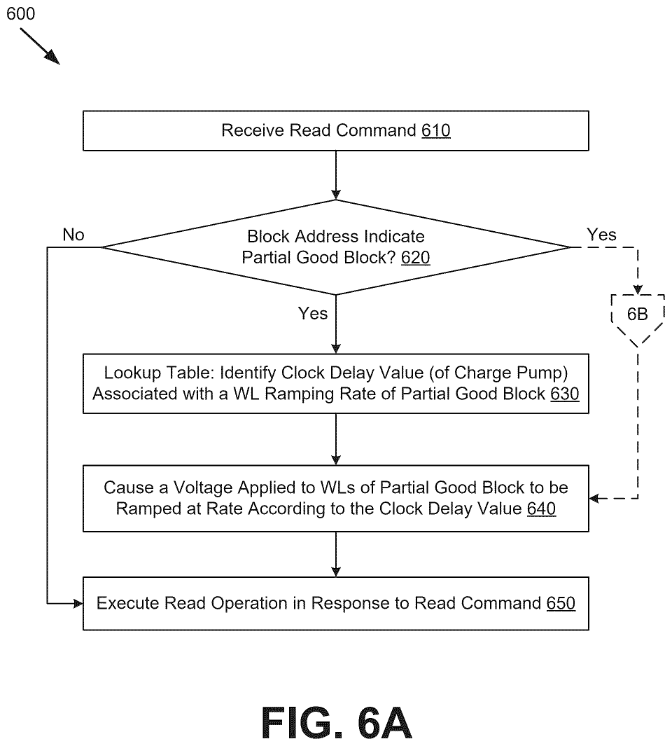

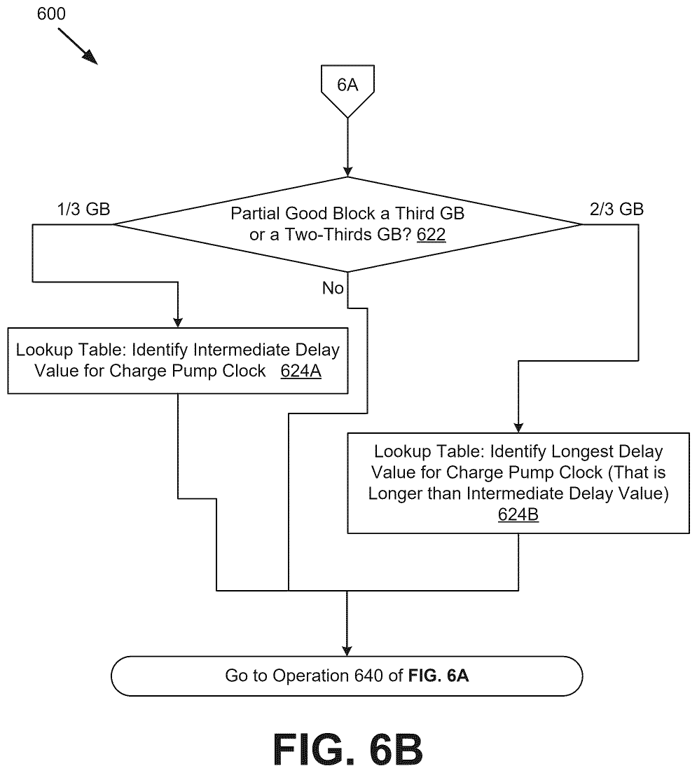

FIG. 6A is a flow diagram of an example method 600 of reducing peak power in response to a read command directed at a partial good block in accordance with other embodiments. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 600 is performed by access management component 113 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 610, a read command is received. For example, the processing logic (e.g., the access management component 113) receives a read command from host system 120 or another agent seeking access to an array on the memory device 130.

At operation 620, a block address is inspected. For example, the processing logic determines whether the block address of the read command indicates the block being read is a partial good block. If the block being read is not a partial good block, the method 600 can flow to the end to simply execute the read operation without adjusting trim settings. Otherwise, the method 600 flows to operation 630, or optionally to the operations of FIG. 6B.

In some embodiments, determining that the received read command is directed to the partial good block includes accessing a system file (e.g., in the local memory 119 or at the array of memory cells 104) in which metadata associated with the plurality of blocks is stored. In embodiments, the metadata in the system file includes an indication of which of the plurality of blocks are partial good blocks. In this way, the metadata associated with particular block addresses can be accessed to determine whether the block is a partial good block.

At operation 630, a clock delay value is identified. For example, the processing logic identifies a clock delay value associated with a wordline ramping rate of the partial good block. In some embodiments, identifying the clock delay value is performed by accessing a data structure (such as a lookup table) in which the clock delay value is indexed to a type of partial good block. Each type of partial good block can thus be associated with a different clock delay value.

At operation 640, a wordline ramping rate is adjusted. For example, the processing logic causes a voltage to be applied to wordlines of the partial good block to be ramped at a rate according to the clock delay value at operation 630. In some embodiments, causing the voltage applied to the wordlines to be ramped according to the clock delay value includes causing a charge pump clock to be slowed by the clock delay value. In embodiments, the charge pump clock drives a charge pump that generates the voltage.

At operation 650, the read operation is executed. For example, the processing logic causes the read operation to be performed in response to the read command received at operation 610. At some point before actual read operation execution, e.g., in preparation to perform the read command, or during read operation execution, the processing logic performs operation 540 in order to reduce the peak consumption current level (e.g., Icc peak current), as discussed.

FIG. 6B is a flow diagram of a variation on the method 600 of FIG. 6A, which deviates when the partial good block is a third or a two-thirds good bock in accordance to some embodiments. For example, in response to determining that the block is a partial good block at operation 620, the processing logic can direct additional operations to consider whether the partial good block is a multi-deck partial good block. By way of example, at operation 622, the processing logic determines whether the partial good block is a third good block or a two-thirds good block. If neither, the method 600 continues to flow as before in FIG. 6A, passing directly to operation 640.

At operation 624A, an intermediate delay is identified. More specifically, in response to determining that the partial good block is a third good block (or 1/3 GB), the processing logic identifies, from the data structure (such as the aforementioned lookup table), the clock delay value to be an intermediate delay value.

At operation 624B, a longest delay value is identified. More specifically, in response to determining that the partial good block is a two-thirds good block (or 2/3 GB), the processing logic identifies, from the data structure (such as the aforementioned lookup table), the clock delay value to be a longest delay value. In some embodiments, the longest delay value is greater than the intermediate delay value and greater than the delay value associated with a half good block, for example. After performing either of operation 624A or operation 624B, the processing logic of the method 600 can go to operation 640 of FIG. 6A and use either of the intermediate or longest delay value to be applied to ch charge pump clock.

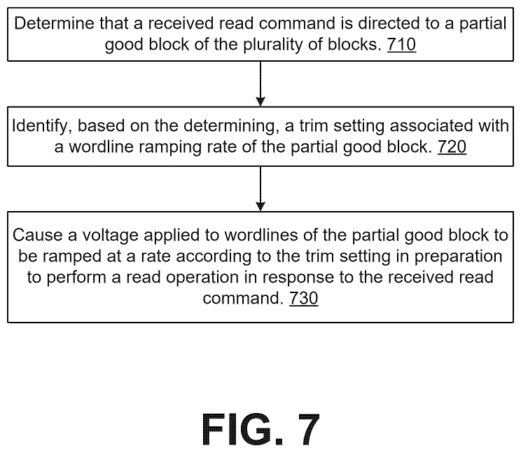

FIG. 7 is a flow diagram of an example method 700 reducing peak power in response to a read command directed at a partial good block in accordance with at least one embodiment. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by access management component 113 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 710, an address of a read command is analyzed. For example, the processing logic determines that a received read command is directed to a partial good block of the plurality of blocks.

At operation 720, a trim setting is identified. For example, the processing logic identifies, based on the determining at operation 710, a trim setting associated with a wordline ramping rate of the partial good block.

At operation 730, a wordline ramping rate is adjusted. More specifically, the processing logic causes a voltage applied to wordlines of the partial good block to be ramped at a rate according to the trim setting in preparation to perform a read operation in response to the received read command.

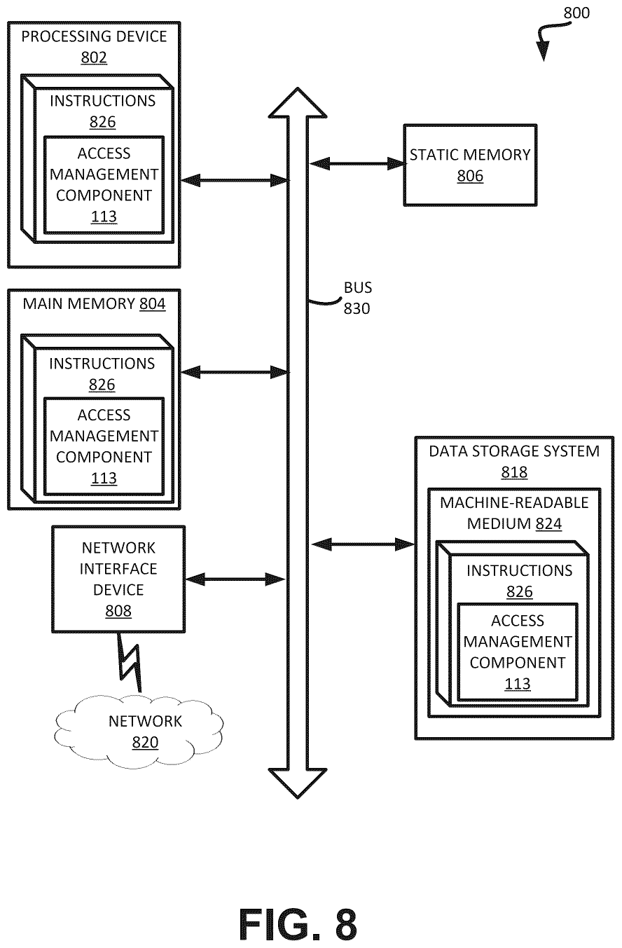

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the access management component 113 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 826 for performing the operations and steps discussed herein. The computer system 800 can further include a network interface device 808 to communicate over the network 820.

The data storage system 818 can include a machine-readable storage medium 824 (also known as a computer-readable medium, such as a non-transitory computer-readable medium) on which is stored one or more sets of instructions 826 or software embodying any one or more of the methodologies or functions described herein. The instructions 826 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 110 of FIG. 1A.

In one embodiment, the instructions 826 include instructions to implement functionality corresponding to the access management component 113 of FIG. 1A). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device comprising a three-dimensional (3D) memory array having a plurality of blocks; and
a processing device coupled to the memory device, the processing device to perform operations comprising:
determining that a received read command is directed to a partial good block of the plurality of blocks;
identifying, based on the determining, a trim setting associated with a wordline ramping rate of the partial good block; and
causing a voltage applied to wordlines of the partial good block to be ramped at a rate according to the trim setting in preparation to perform a read operation in response to the received read command.

2. The system of claim 1, wherein determining that the received read command is directed to the partial good block comprises accessing a system file in which metadata associated with the plurality of blocks is stored, the system file comprising an indication of which of the plurality of blocks are partial good blocks.

3. The system of claim 1, wherein the trim setting comprises a clock delay value and causing the voltage applied to the wordlines to be ramped according to the trim setting comprises causing a charge pump clock to be slowed by the clock delay value, the charge pump clock to drive a charge pump that generates the voltage.

4. The system of claim 3, wherein the processing device is to identify the clock delay value by accessing a data structure in which the clock delay value is indexed to a type of partial good block, and wherein the operations further comprise:
determining that the partial good block is one of a two-thirds good block or a third good block; and
identifying, from the data structure, the clock delay value to be one of an intermediate delay value or a longest delay value, respectively for the two-thirds good block or the third good block, wherein the longest delay value is greater than the intermediate delay value.

5. The system of claim 1, wherein causing the voltage applied to the wordlines to be ramped occurs during a hit pass voltage operation that precedes the read operation.

6. The system of claim 1, wherein the operations further comprise determining that the partial good block spans across multiple dies of the memory device, and wherein identifying the trim setting is also based on a number of dies of the multiple dies.

7. The system of claim 6, wherein the trim setting comprises a clock delay value associated with the number of dies and causing the voltage applied to the wordlines to be ramped according to the trim setting comprises causing a charge pump clock to be slowed by the clock delay value, the charge pump clock to drive a charge pump that generates the voltage.

8. A method comprising:
determining, by a processing device coupled to a memory device, that a received read command is directed to a partial good block of a plurality of blocks of a three-dimensional memory array;
identifying, based on the determining, a trim setting associated with a wordline ramping rate of the partial good block; and
causing, by the processing device, a voltage applied to wordlines of the partial good block to be ramped at a rate according to the trim setting in preparation to perform a read operation in response to the received read command.

9. The method of claim 8, wherein determining that the received read command is directed to the partial good block comprises accessing a system file in which metadata associated with the plurality of blocks is stored, the system file comprising an indication of which of the plurality of blocks are partial good blocks.

10. The method of claim 8, wherein the trim setting comprises a clock delay value and causing the voltage applied to the wordlines to be ramped according to the trim setting comprises causing a charge pump clock to be slowed by the clock delay value, the charge pump clock to drive a charge pump that generates the voltage.

11. The method of claim 10, wherein identifying the clock delay value comprises accessing a data structure in which the clock delay value is indexed to a type of partial good block, the method further comprising:
determining that the partial good block is one of a two-thirds good block or a third good block; and
identifying, from the data structure, the clock delay value to be one of an intermediate delay value or a longest delay value, respectively for the two-thirds good block or the third good block, wherein the longest delay value is greater than the intermediate delay value.

12. The method of claim 8, wherein causing the voltage applied to the wordlines to be ramped occurs during a hit pass voltage operation that precedes the read operation.

13. The method of claim 8, further comprising determining that the partial good block spans across multiple dies of the memory device, and wherein identifying the trim setting is also based on a number of dies of the multiple dies.

14. The method of claim 13, wherein the trim setting comprises a clock delay value associated with the number of dies and causing the voltage applied to the wordlines to be ramped according to the trim setting comprises causing a charge pump clock to be slowed by the clock delay value, the charge pump clock to drive a charge pump that generates the voltage.

15. A system comprising:
a memory device comprising a three-dimensional (3D) memory array having a plurality of blocks; and
a processing device coupled to the memory device, the processing device to perform operations comprising:
determining that a received read command is directed to a partial good block of the plurality of blocks;
accessing a lookup table to identify, based on the determining, a clock delay value associated with a wordline ramping rate of the partial good block; and
causing a voltage applied to wordlines of the partial good block to be ramped at a rate that is slowed by the clock delay value before performing a read operation in response to the received read command.

16. The system of claim 15, wherein determining that the received read command is directed to the partial good block comprises accessing a system file in which metadata associated with the plurality of blocks is stored, the system file comprising an indication of which of the plurality of blocks are partial good blocks.

17. The system of claim 15, wherein causing the voltage applied to the wordlines to be ramped according to the clock delay value comprises causing a charge pump clock to be slowed by the clock delay value, the charge pump clock to drive a charge pump that generates the voltage.

18. The system of claim 15, wherein the clock delay value in the lookup table is indexed according to a type of the partial good block, and wherein the operations further comprise:
determining that the partial good block is one of a two-thirds good block or a third good block; and
identifying, from the lookup table, the clock delay value to be one of an intermediate delay value or a longest delay value, respectively for the two-thirds good block or the third good block, wherein the longest delay value is greater than the intermediate delay value.

19. The system of claim 15, wherein causing the voltage applied to the wordlines to be ramped occurs during a hit pass voltage operation that precedes the read operation.

20. The system of claim 15, wherein the operations further comprise determining that the partial good block spans across multiple dies of the memory device, wherein:
accessing the lookup table to determine the clock delay value is also based on a number of dies of the multiple dies, and
causing the voltage applied to the wordlines to be ramped according to the clock delay value comprises causing a charge pump clock to be slowed by the clock delay value, the charge pump clock to drive a charge pump that generates the voltage.
